(19) United States
(12) Patent Application Publication
(10) Pub. No.: US 2026/0011566 A1
(43) Pub. Date: Jan. 8, 2026

(54) METHOD FOR PROCESSING A WAFER

(71) Applicant: NANYA TECHNOLOGY CORPORATION, New Taipei City (TW)

(72) Inventor: Wei-Chuan FANG, New Taipei City (TW)

(21) Appl. No.: 18/764,394

(22) Filed: Jul. 5, 2024

(51) Int. Cl. H01L 21/3105; H01L 21/02; H01L 21/3205

(52) U.S. Cl. CPC H01L 21/31053; H01L 21/0217; H01L 21/32051

(57) ABSTRACT

A method for processing a wafer is provided. The method includes providing a wafer, in which the wafer has a first region and a second region, and the second region is between an edge of the wafer and the first region; depositing a first metallic layer on the wafer; depositing a cap layer on the first metallic layer; disposing a dielectric layer on the cap layer, in which the dielectric layer covers a sidewall of the first metallic layer and a sidewall of the cap layer; performing a polishing process to the dielectric layer, such that a consumed portion of the cap layer and a consumed portion of the first metallic layer is formed in the second region of the wafer.

### BACKGROUND

### FIELD OF INVENTION

The present invention relates to a method for processing a wafer.

### DESCRIPTION OF RELATED ART

Wafers are widely used in modern technology. Therefore, an appropriate processing method for the wafers is needed.

### SUMMARY

According to some embodiments of the present disclosure, a method for processing a wafer is provided. The method may allow wafers to be processed without the edge beam removal (EBR) process. Therefore, the present method may reduce issues of dishing and edge consumption of the nitrided layer over the gate electrode, thus maintaining the thickness of the nitrided layer to avoid short circuiting between a landing plate of a metallization layer (M0) and the gate electrode. Furthermore, after processing, consumed portions of the nitrided layer and gate electrode layer may be on the non-active region of the wafer, thus improving the yield rate of the wafer. The yield rates of the edge region of the wafer at different temperatures improve about 6% to 8%. In addition, the yield rates of the average region at different temperatures also improve about 1.6% to 1.8%.

According to some embodiments of the present disclosure, a method for processing a wafer is provided. The method includes following steps. A wafer is provided, in which the wafer has a first region and a second region, and the second region is between an edge of the wafer and the first region. A first metallic layer is deposited on the wafer. A cap layer is deposited on the first metallic layer. A dielectric layer is disposed on the cap layer, in which the dielectric layer covers a sidewall of the first metallic layer and a sidewall of the cap layer. A polishing process is performed to the dielectric layer, such that a consumed portion of the cap layer and a consumed portion of the first metallic layer are formed in the second region of the wafer.

According to some embodiments of the present disclosure, the method described above further includes the following steps. After the polishing process, a second metallic layer is deposited on the cap layer.

According to some embodiments of the present disclosure, the method is described above, in which a width of the first region is larger than a width of the second region.

According to some embodiments of the present disclosure, the method described above further includes the following steps. After depositing the dielectric layer, a wafer edge exposure process is performed to a third region of the wafer, in which the third region is between the edge of the wafer and the second region of the wafer.

According to some embodiments of the present disclosure, the method is described above, in which a distance between the edge of the wafer and a first edge of the second region is in a range from about 0.6 to 1 mm, and a distance between the edge of the wafer and a second edge of the second region is in a range from about 1.8 to 2.2.

According to some embodiments of the present disclosure, the method is described above, in which the wafer has a notch extending from the edge of the wafer into the first region of the wafer through the second region of the wafer.

According to some embodiments of the present disclosure, the method is described above, in which the cap layer includes SiN.

According to some embodiments of the present disclosure, the method is described above, in which the polishing process is performed such that the thickness of the cap layer decreases from an edge of the cap layer to a center of the cap layer.

According to some embodiments of the present disclosure, the method is described above, in which a width of the consumed portion of the cap layer and a width of the consumed portion of the first metallic layer are less than a width of the second region.

According to some embodiments of the present disclosure, a method for processing a wafer is provided. The method includes following steps. A wafer is provided, in which the wafer has a center region, a first ring region surrounding the center region, and a second ring region surrounding the first ring region. A material layer is deposited over the wafer. A dielectric layer is disposed on the material layer. A polishing process is performed to the wafer, such that a consumed portion of the material layer is formed in the first ring region of the wafer.

According to some embodiments of the present disclosure, the method described above further includes the following steps. Before the polishing process, a wafer edge exposure process is performed to the wafer.

According to some embodiments of the present disclosure, the method is described above, in which a width of the first ring region is between a width of the center region and a width of the second ring region.

According to some embodiments of the present disclosure, the method is described above, in which the material layer includes a first metallic layer and a nitrided layer on the first metallic layer.

According to some embodiments of the present disclosure, the method is described above, in which the second ring region of the wafer is free of the material layer.

According to some embodiments of the present disclosure, the method is described above, in which the polishing process is performed when the dielectric layer is in the center region, the first ring region, and the second ring region.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for processing a wafer in accordance with some embodiments.

FIG. 2 is a top view of a wafer in accordance with some embodiments of the present disclosure.

FIGS. 3 through 8 are cross-sectional views taken along a line A-A’ of FIG. 2 at various stages of process in accordance with some embodiments of the present disclosure.

FIG. 9 is a schematic diagram of an integrated circuit device in accordance with an example of the present disclosure.

FIG. 10 is a graph illustrating experimental results showing yield rates at low temperature according to some embodiments of the present disclosure.

FIG. 11 is a graph illustrating experimental results showing yield rates at high temperature according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

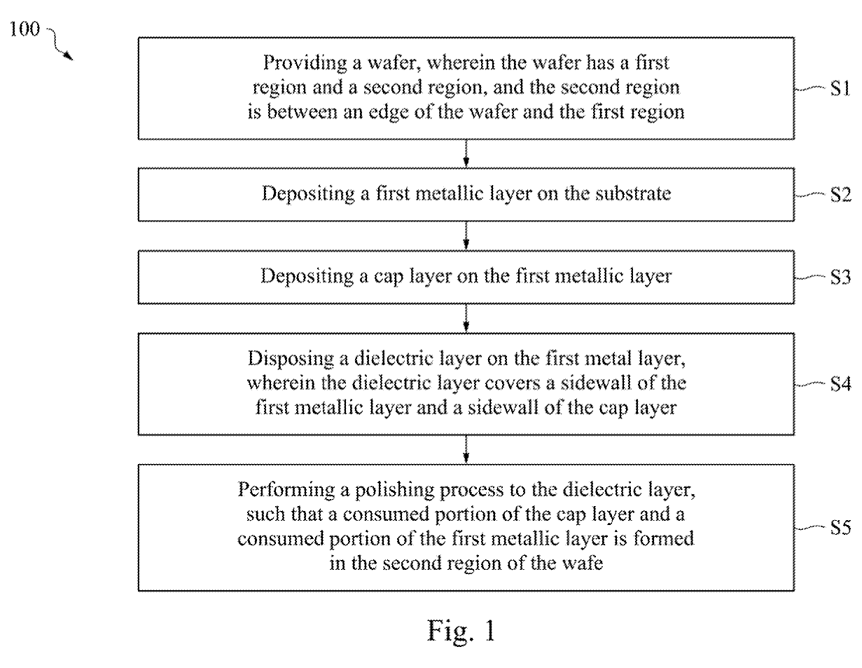

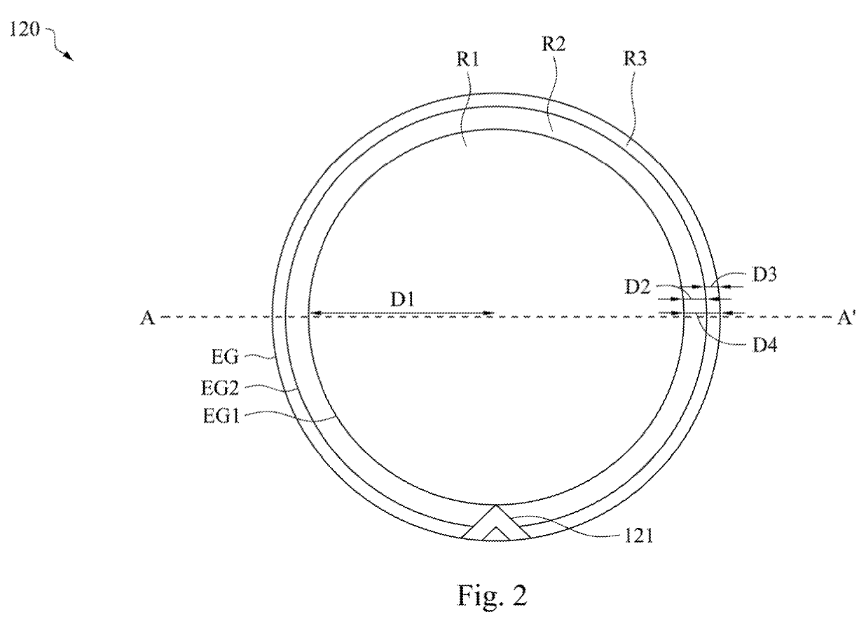

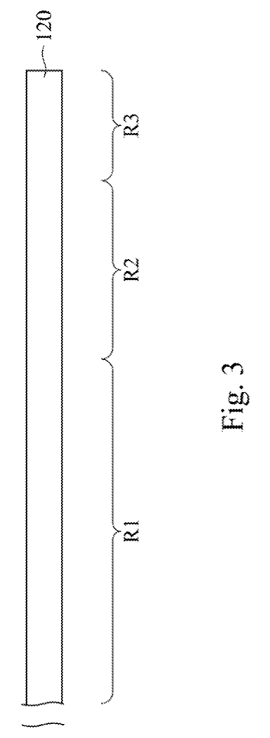

FIG. 1 is a flow chart of a method 100 for processing a wafer 120 in accordance with some embodiments. FIG. 2 is a top view of a wafer 120 in accordance with some embodiments of the present disclosure. FIGS. 3 through 8 are cross-sectional views taken along a line A-A’ of FIG. 2 at various stages of process in accordance with some embodiments of the present disclosure. The illustration is merely exemplary and is not intended to limit beyond what is specifically recited in the claims that follow. It is understood that additional operations may be provided before, during, and after the operations S1-S5 shown by FIG. 1, and some of the operations S1-S5 described below can be replaced or eliminated for additional embodiments of the method. The order of the operations/processes may be interchangeable.

Referring to FIG. 1, FIG. 2 and FIG. 3, the method 100 begins at operation S1 where a wafer 120 is provided. The wafer 120 has a first region R1, a second region R1 and a third region R3. The first region R1 is also called a center region and known as an active area or an effective area, where the IC devices to formed. The second region R2 is between an edge EG of the wafer 120 and the first region R1, in which the second region R2 surrounds the first region R1. The third region R3 is between an edge EG of the wafer 120 and the second region R2, in which the third region R3 surrounds the second region R2. The second region R2 and the third region R3 are also called the first ring region and the second ring region, respectively, and also known as the non-active area which is not configured to manufacture IC devices due to the fact that the second region R2 and the third region R3 are easily damaged during processing.

In some embodiments, a width of the first region R1 is larger than a width of the second region R2, and the width of the second region R2 is larger than a width of the third region R3. In detail, the first region R1 has a radius, which is a distance D1 between a center of the wafer 120 and a first edge EG1 of the second region R2, and the width of the first region R1 is twice the radius. The width of the second region R2 is a distance D2 between the first edge EG1 and a second edge EG2 of the second region R2. The width of the third region R3 is a distance D3 between the second edge EG2 of the second region R2 and an edge EG of the wafer 120. In the present embodiment, the distance D1 is about 148 mm to 150 mm. A distance D4 between the edge EG of the wafer 120 and a first edge EG1 of the second region R2 is in a range from about 1.8 mm to 2.2 mm, and the distance D3 between the edge EG of the wafer 120 and a second edge EG2 of the second region R2 is in a range from about 0.6 mm to 1 mm. The distance D2 is the distance D4 minus the distance D3. However, it should be noticed that the distance D1, D2, D3 and D4 may adopt any appropriate configurations without such limitation.

In some other embodiments, the wafer 120 further includes a notch 121, which is prone to identify the orientation or the crystal orientation of the wafer 120. For example, in the present embodiment, the notch 121 is between the edge of the wafer 120 and the first region R1, and extends from the edge EG of the wafer 120 into the first region R1 of the wafer 120 through the second region R2 and the third region R3 of the wafer 120. However, it should be noticed that the notch 121 may adopt any appropriate configurations without such limitation.

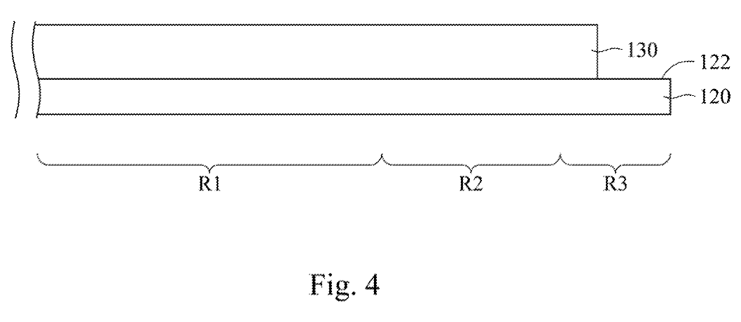

Referring to FIG. 1 and FIG. 4, the method 100 proceeds to operation S2 where a first metallic layer 130 is deposited on the wafer 120. The first metallic layer 130 may be deposited on the wafer 120 by any appropriate processes. For example, in some embodiments, the first metallic layer 130 may be deposited by the chemical vapor deposition (CVD), atomic layer deposition (ALD), physical vapor deposition (PVD), the like, and/or the combination thereof. Furthermore, a length of the first metallic layer 130 may be adjusted according to the functional requirements. For example, in the present embodiment, the deposition is performed such that the first metallic layer 130 overlaps the first region R1 and the second region R2, and the top surface 122 of the third region R3 of the wafer 120 is exposed by the first metallic layer 130. However, it should be noticed that the first metallic layer 130 may adopt any appropriate configurations without such limitation.

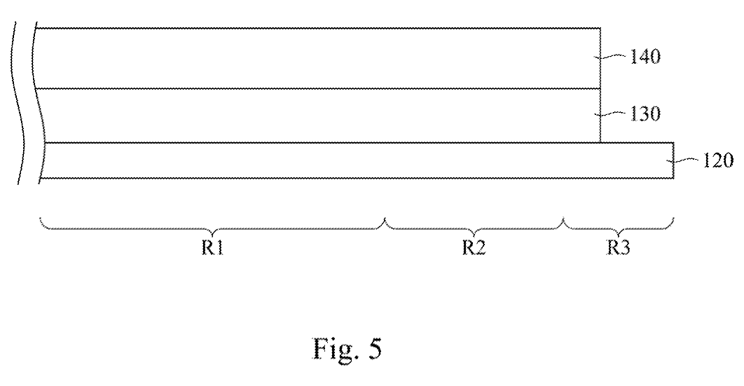

Referring to FIG. 1 and FIG. 5, the method 100 proceeds to operation S3 where a cap layer 140 is deposited on the first metallic layer 130. In some embodiments, the cap layer 140 may be silicon nitride (SiN). The cap layer 140 may be deposited on the wafer 120 by any appropriate processes. For example, in some embodiments, the cap layer 140 may be deposited by CVD, ALD, PVD, the like, and/or the combination thereof. Furthermore, a length of the cap layer 140 may be adjusted according to the functional requirements. For example, in the present embodiment, the deposition is performed such that the cap layer 140 overlaps the first metallic layer 130 such that the third region R3 of the wafer 120 is free of the cap layer 140 and the first metallic layer 130. However, it should be noticed that the cap layer 140 may adopt any appropriate configurations without such limitation. In addition, the cap layer 140 may be any appropriate materials.

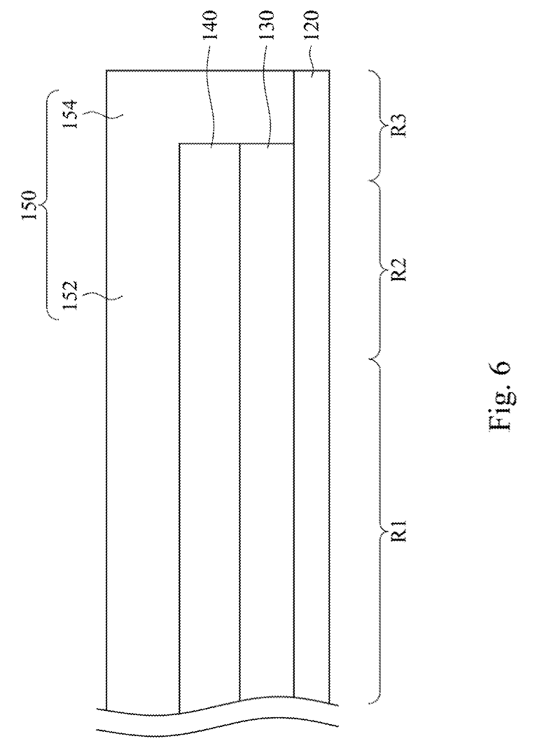

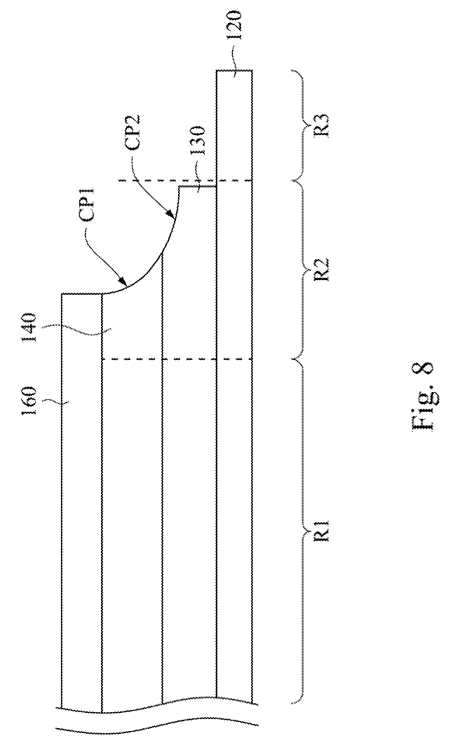

Referring to FIG. 1 and FIG. 6, the method 100 proceeds to operation S4 where a dielectric layer 150 is disposed on the cap layer 140. The dielectric layer 150 may any appropriate dielectric layers. For example, in the present embodiment, the dielectric layer 150 may be a spin-on dielectric (SOD) layer, in which the thickness of the dielectric layer 150 may gradually decreases from the edge of the dielectric layer 150 to the center of the dielectric layer 150 due to the characteristic of SOD. However, it should be noticed that the dielectric layer 150 may adopt any appropriate configurations without such limitation. The dielectric layer 150 may be disposed by any appropriate processes. For example, in some embodiments, the dielectric layer 150 may be disposed by a spin coating method. Furthermore, a shape of the dielectric layer 150 may be adjusted according to the functional requirement. For example, in the present embodiment, the dielectric layer 150 wraps around the first metallic layer 130 and the cap layer 140. In detail, the dielectric layer 150 has a horizontal portion 152 and a vertical portion 154. The horizontal portion 152 overlaps the cap layer 140 and the first metallic layer 130. The vertical portion 154 is in contact with the horizontal portion 152 and located within the region R3 of the wafer 120, in which the vertical portion 154 covers a sidewall of the first metallic layer 130 and a sidewall of the cap layer 140. The dielectric layer 150 may limit the damages due to the subsequent processes in the region R2 and region R3 of the wafer 120 such that the portions of the first metallic layer 130 and the cap layer 140 in the region R1 may remain undamaged. Therefore, the thickness of the cap layer 140 may be maintained such that the cap layer 140 may prevent the first metallic layer 130 from short circuiting with the second metallic layer 160 in the first region R1 (refer to FIG. 8).

In some embodiments, after depositing the dielectric layer 150, a wafer edge exposure process (WEE) is performed to the third region R3 of the wafer 120. The wafer edge exposure process may be performed by any appropriate methods. For example, in some embodiments, the wafer edge exposure process may be first performed by forming a photoresist on the wafer 120. Following, the photoresist at the edge of the wafer 120 is exposed by an optical mask. Following, the photoresist at the edge of the wafer 120 is removed by a lithography process. Therefore, the uniformity and the thickness of the wafer 120 may be improved. However, it should be noticed that WEE may adopt any appropriate operations without such limitation.

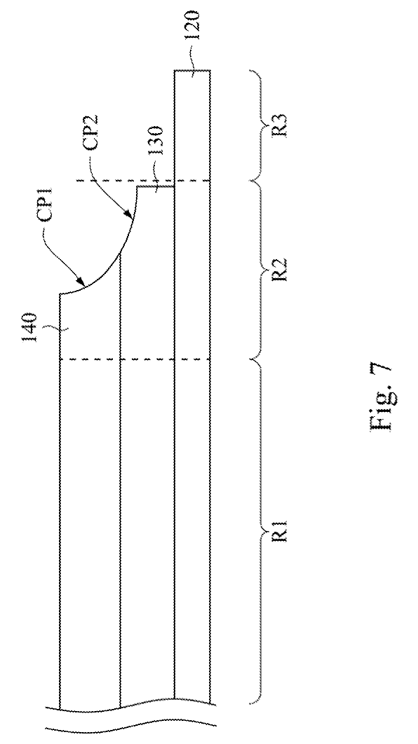

Referring to FIG. 1 and FIG. 7, the method 100 proceeds to operation S5 where a polishing process is performed to the dielectric layer 150, in which the polishing process is performed when the dielectric layer 150 is in the first region R1, the second region R2, and the third region R3. The polishing process may be performed by any appropriate methods. For example, in some embodiments, the dielectric layer 150 may be removed by suitable planarization process, such as a chemical-mechanical polish (CMP) process. In addition, after the polishing process, the thickness of the cap layer 140 decreases from the edge of the cap layer 140 to the center of the cap layer 140, and a consumed portion CP1 of the cap layer 140 and a consumed portion CP2 of the first metallic layer 130 are formed in the second region R2 of the wafer 120, in which a width of the consumed portion CP1 of the cap layer 140 and a width of the consumed portion CP2 of the first metallic layer 130 are less than the width of the second region R2. The consumed portions CP1 and CP2 are concentrated in the second region R2 due to the limitation of the dielectric layer 150 (referring to FIG. 6), such that the first region R1 may be kept undamaged thus improving the yield rate of the wafer 120.

Referring to FIG. 1 and FIG. 8, the method 100 proceeds to operation S6 where a second metallic layer 160 is deposited on the cap layer 140 after the polishing process, in which the cap layer 140 in the first region R1 separates the second metallic layer 160 from the first metallic layer 130 such that the second metallic layer 160 is not short-circuited with the first metallic layer 130. The second metallic layer 160 may be deposited on the wafer 120 by any appropriate processes. For example, in some embodiments, the second metallic layer 160 may be deposited by CVD, ALD, PVD, the like, and/or the combination thereof. Furthermore, a length of the second metallic layer 160 may be adjusted according to the functional requirements. For example, in some embodiments, the second metallic layer 160 may cover the first metallic layer 130 and the cap layer 140. However, it should be noticed that the second metallic layer 160 may adopt any appropriate configurations without such limitation.

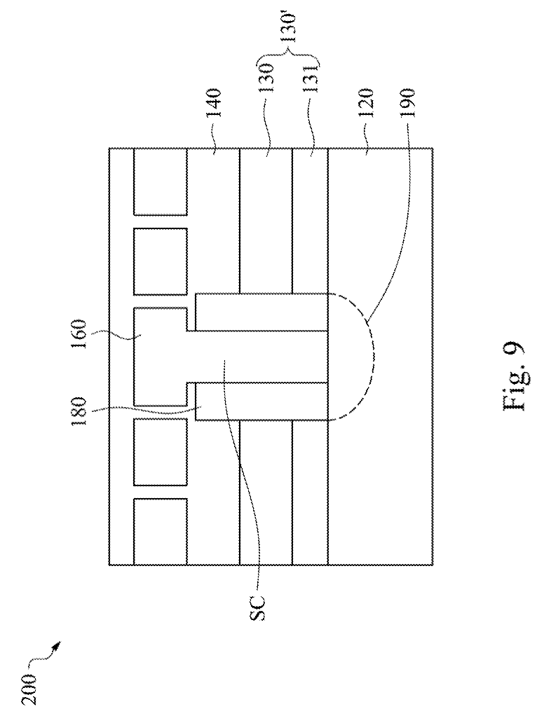

FIG. 9 is a schematic diagram of an integrated circuit device 200 in accordance with an example of the present disclosure. In the present example, before the operation S2, a first dielectric layer 131 may be formed on the wafer 120. Then the first metallic layer 130 is formed on the first dielectric layer 131, as the operation S2 (referring to FIG. 1). The first metallic layer 130 may be also called a gate electrode, and the first dielectric layer 131 may be also called a gate dielectric layer in the context. In some embodiments, the first dielectric layer 131 may be deposited on the wafer 120 by CVD, ALD, PVD, the like, and/or the combination thereof. Furthermore, the first dielectric layer 131 may be any appropriate materials. The first dielectric layer 131 may be made of dielectric material, polymer materials, or any other appropriate materials.

The first dielectric layer 131 and the first metallic layer 130 may be patterned, for example, by a photolithography process and an etching process, into a gate structure 130’. Stated differently, each of the gate structures 130’ may include the first metallic layer 130 and the first dielectric layer 131.

After the formation of the gate structure 130’, a source/drain region 190 may be formed adjacent to a channel region below the gate structure 130’. The source/drain region 190 may be deposited by doping method, ion implantation method, the like, and/or the combination thereof. Then, the operations S3-S5 (referring to FIG. 1) are performed to form the cap layer 140.

Furthermore, after the operation S5 (referring to FIG. 1), a source/drain contact SC is formed over the source/drain region 190. The formation of the source/drain contact SC may include etching a source/drain opening to expose the source/drain region 190 and filling the source/drain opening with a conductive material. Prior to the filling of the conductive material, the second dielectric layer 180 may be formed on sidewalls of the source/drain opening and exposing the source/drain region 190. The second dielectric layer 180 may be made of dielectric material, polymer materials, or any other appropriate materials. Through the configuration, after the formation of the source/drain contact SC, the second dielectric layer 180 separates the source/drain contact SC from the gate structure 130’. In some embodiments, the second dielectric layer 180 may be deposited by CVD, ALD, PVD, the like, and/or the combination thereof. After the formation of the source/drain contact SC, a second metallic layer 160 may be formed on the source/drain contact SC as illustrated in operation S6 (referring to FIG. 1). The second metallic layer 160 may be a metallization layer (M0) including plural metal features (e.g., metal lines and/or metal vias). For example, a metal line of the second metallic layer 160 is in contact with the source/drain contact SC.

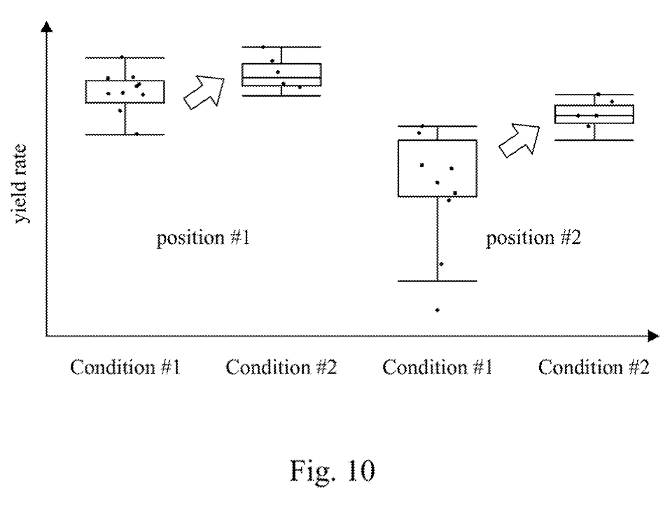

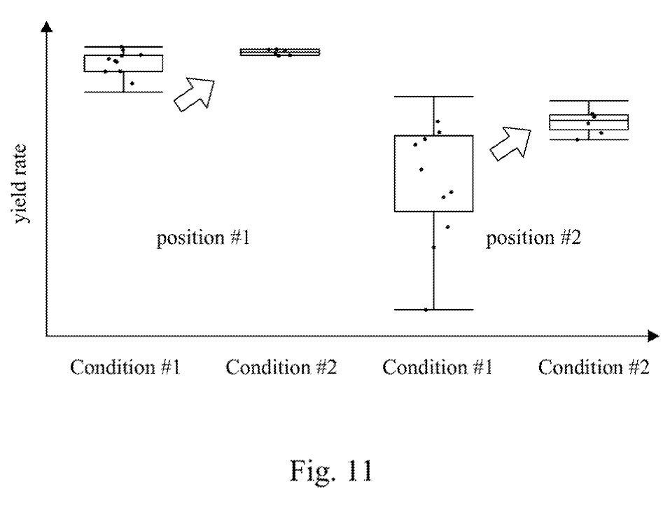

FIG. 10 is a graph illustrating experimental results showing yield rates at low temperature according to some embodiments of the present disclosure. FIG. 11 is a graph illustrating experimental results showing yield rates at high temperature according to some embodiments of the present disclosure. The yield rate is shown on the vertical axis in FIGS. 10 and 11. The different conditions are shown on the horizontal axis in FIGS. 10 and 11. Position #1 indicates an average result of the yield rate of the entire wafer 120. Position #2 indicates a result of the yield rate of the edge of the wafer 120. In Condition #1, the wafer 120 is processed without performing the method 100. In Condition #2, the wafer 120 is processed by the method 100.

Comparing Condition #2 with Condition #1, the yield rates of the wafer 120 are increased. These graphs show that, by performing the method 100, the average region of the wafer 120 and the edge region of the wafer 120 has higher yield rates, which is beneficial for device manufacturing under the high temperature and low temperature. For example, herein, the yield rates of the edge region of the wafer 120 at different temperature improve about 6% to 8%. The yield rates of the average region of the wafer 120 at different temperature improve about 1.6% to 1.8%.

According to some embodiments of the present disclosure, a method for processing a wafer is provided. The method may allow wafers to be processed without the edge beam removal (EBR) process. Therefore, the present method may reduce issues of dishing and edge consumption of the nitrided layer over the gate electrode, thus maintaining the thickness of the nitrided layer to avoid short circuiting between a landing plate of a metallization layer (M0) and the gate electrode. Furthermore, after processing, consumed portions of the nitrided layer and gate electrode layer may be on the non-active region of the wafer, thus improving the yield rate of the wafer. The yield rates of the edge region of the wafer at different temperatures improve about 6% to 8%. In addition, the yield rates of the average region at different temperatures also improve about 1.6% to 1.8%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for processing a wafer, comprising:
providing a wafer, wherein the wafer has a first region and a second region, and the second region is between an edge of the wafer and the first region;
depositing a first metallic layer on the wafer;
depositing a cap layer on the first metallic layer;
disposing a dielectric layer on the cap layer, wherein the dielectric layer covers a sidewall of the first metallic layer and a sidewall of the cap layer; and
performing a polishing process to the dielectric layer, such that a consumed portion of the cap layer and a consumed portion of the first metallic layer are formed in the second region of the wafer.

2. The method of claim 1, further comprising:
after the polishing process, depositing a second metallic layer on the cap layer.

3. The method of claim 1, wherein a width of the first region is larger than a width of the second region.

4. The method of claim 1, further comprising:
after depositing the dielectric layer, performing a wafer edge exposure process to a third region of the wafer, wherein the third region is between the edge of the wafer and the second region of the wafer.

5. The method of claim 1, wherein a distance between the edge of the wafer and a first edge of the second region is in a range from about 0.6 to 1 mm, and a distance between the edge of the wafer and a second edge of the second region is in a range from about 1.8 to 2.2.

6. The method of claim 1, wherein the wafer has a notch extending from the edge of the wafer into the first region of the wafer through the second region of the wafer.

7. The method of claim 1, wherein the cap layer comprises SiN.

8. The method of claim 1, wherein the polishing process is performed such that a thickness of the cap layer decreases from an edge of the cap layer to a center of the cap layer.

9. The method of claim 1, wherein a width of the consumed portion of the cap layer and a width of the consumed portion of the first metallic layer are less than a width of the second region.

10. A method for processing a wafer, comprising:
providing a wafer, wherein the wafer has a center region, a first ring region surrounding the center region, and a second ring region surrounding the first ring region;
depositing a material layer over the wafer;
disposing a dielectric layer on the material layer; and
performing a polishing process to the wafer, such that a consumed portion of the material layer is formed in the first ring region of the wafer.

11. The method of claim 10, further comprising:
before the polishing process, performing a wafer edge exposure process to the wafer.

12. The method of claim 10, wherein a width of the first ring region is between a width of the center region and a width of the second ring region.

13. The method of claim 10, wherein the material layer comprises a first metallic layer and a nitrided layer on the first metallic layer.

14. The method of claim 13, wherein the second ring region of the wafer is free of the material layer.

15. The method of claim 10, wherein the polishing process is performed when the dielectric layer is in the center region, the first ring region, and the second ring region.
